(19) United States
(12) Patent Application Publication
(10) Pub. No.: US 2026/0020423 A1
(43) Pub. Date: Jan. 15, 2026

(54) DISPLAY MODULE AND METHOD OF MANUFACTURING THE SAME

(71) Applicant: EPISTAR CORPORATION, Hsinchu (TW)

(72) Inventor: Min-Hsun HSIEH, Hsinchu (TW)

(21) Appl. No.: 19/237,098

(22) Filed: Jun. 13, 2025

(30) Foreign Application Priority Data
Jun. 13, 2024 (TW) 113121820

(51) Int. Cl. H10H 29/80; H01L 25/075; H10H 29/02; H10H 29/853; H10H 29/855

(52) U.S. Cl. CPC H10H 29/942; H10H 29/02; H10H 29/853; H10H 29/855; H01L 25/0753

(57) ABSTRACT

A pixel module includes a substrate, a first sub-pixel unit, and a second sub-pixel unit. The first sub-pixel unit is disposed on the substrate, and includes a first light-emitting unit, a second light-emitting unit, and a light-transmitting layer. The first light-emitting unit and the second light-emitting unit are connected in series through the light-transmitting layer and are located on the same side of the light-transmitting layer. The second sub-pixel unit is disposed on the substrate, and the first sub-pixel unit and the second sub-pixel unit can emit different color lights.

This application claims priority to the benefit of TW patent application Ser. No. 11/312,1820 filed on Jun. 13, 2024 and the entire content of which is hereby incorporated by reference herein in its entirety.

### TECHNICAL FIELD

The present disclosure relates to a display module, and in particular to a display module in which a sub-pixel includes two light-emitting units connected in series in opposite directions.

### RELATED TECHNOLOGIES

As the number of pixels in a display panel increases, energy consumption control of display modules has become increasingly important. How to reduce the energy consumption in each sub-pixel has also gradually attracted attention.

### SUMMARY

An embodiment of the present disclosure provides a display module, which includes a substrate, a first sub-pixel unit, and a second sub-pixel unit. The first sub-pixel unit and the second sub-pixel unit are disposed on the substrate, and the first sub-pixel unit and the second sub-pixel unit are capable of emitting different color lights. The first sub-pixel unit includes a first light-emitting unit, a second light-emitting unit, and a light-transmitting layer. The first light-emitting unit and the second light-emitting unit are connected in series in opposite directions through the light-transmitting layer, and are located on a same side of the light-transmitting layer.

### BRIEF DESCRIPTION OF THE DRAWINGS

The following provides a detailed description of embodiments of the present disclosure with reference to the accompanying drawings. The drawings are not drawn to scale and are provided for illustrative purposes only. The sizes of the components in the drawings may be arbitrarily enlarged or reduced in order to clearly show the features of the various embodiments of the present disclosure. The same or similar components in the drawings are denoted by the same reference numerals.

FIG. 1 shows a top view of a display module according to an embodiment.

FIG. 2 shows a cross-sectional view along line AA′ in FIG. 1.

FIG. 3(a) shows a cross-sectional view of a first light-emitting unit according to an embodiment.

FIG. 3(b) shows a cross-sectional view of a second light-emitting unit according to an embodiment.

FIGS. 4 to 5 show a manufacturing process of a sub-pixel unit according to an embodiment.

FIGS. 6 to 8 show a manufacturing process of a sub-pixel unit according to another embodiment.

FIG. 9 shows a cross-sectional view of a sub-pixel unit according to an embodiment.

FIG. 10(a) shows a cross-sectional view of a first light-emitting unit according to another embodiment.

FIG. 10(b) shows a cross-sectional view of a second light-emitting unit according to another embodiment.

### EMBODIMENTS

It should be understood that when a component is described as being “on” or “connected to” another component, it may be directly on or connected to the other component, or indirectly on or connected to the other component through one or more intervening components. In contrast, when a component is referred to as being “directly on” or “directly connected to” another component, there are no intervening components between them. The term “connected” may refer to physical and/or electrical connections.

An embodiment of the present disclosure provides a display module, in which a sub-pixel unit includes two vertical light-emitting diodes connected in series in opposite directions through a light-transmitting layer, so as to reduce the power consumption of the display circuit.

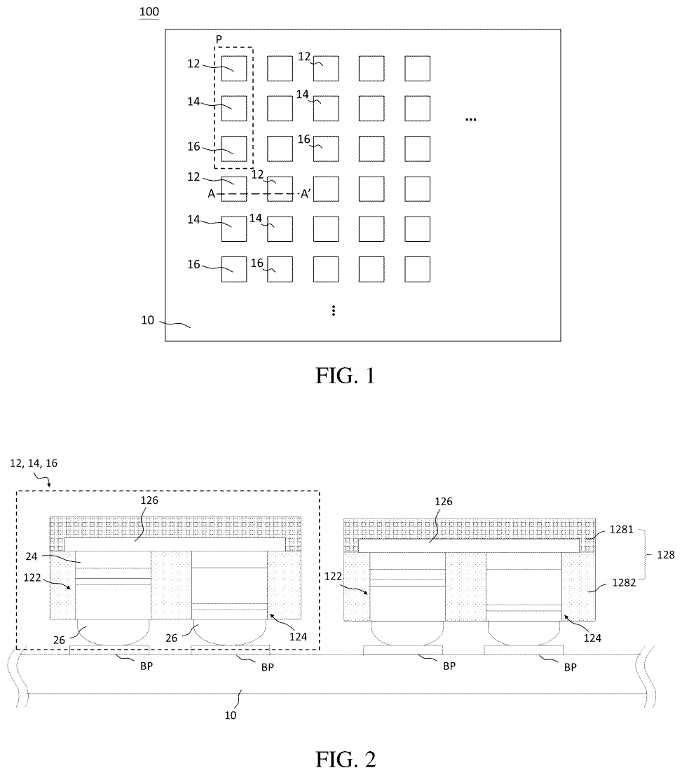

FIG. 1 shows a top view of a display module 100 according to one embodiment, and FIG. 2 shows a cross-sectional view along line AA′ in FIG. 1. The display module 100 includes a substrate 10 and a plurality of pixels P, wherein the plurality of pixels P are arranged in an array on the substrate 10. A pixel P includes a first sub-pixel unit 12, a second sub-pixel unit 14, and a third sub-pixel unit 16, which are electrically connected to the substrate 10. The first sub-pixel unit 12, the second sub-pixel unit 14, and the third sub-pixel unit 16 can emit different color lights, such as red, blue, and green light, respectively. The substrate 10 can be a printed circuit board (PCB) or a glass circuit board, and includes multiple contact electrodes BPs for electrical connection with the sub-pixel units 12, 14, and 16. The substrate 10 can provide electrical signals to drive the sub-pixel units 12, 14, and 16 to emit light.

The first sub-pixel unit 12 includes a first light-emitting unit 122, a second light-emitting unit 124, and a light-transmitting layer 126. The first light-emitting unit 122 and the second light-emitting unit 124 are connected in series in opposite directions through the light-transmitting layer 126 and are located on the same side of the light-transmitting layer 126. In one embodiment, the contact resistance between the light-transmitting layer 126 and the light-emitting units 122, 124 is less than 10⁻² Ω·cm, so as to provide electrical connection between the light-emitting units 122 and 124. The light-transmitting layer 126 includes a transparent conductive material such as indium tin oxide (ITO) or indium zinc oxide (IZO), and the transmittance of the light-transmitting layer 126 for the light emitted from the first and second light-emitting units 122, 124 exceeds 80%.

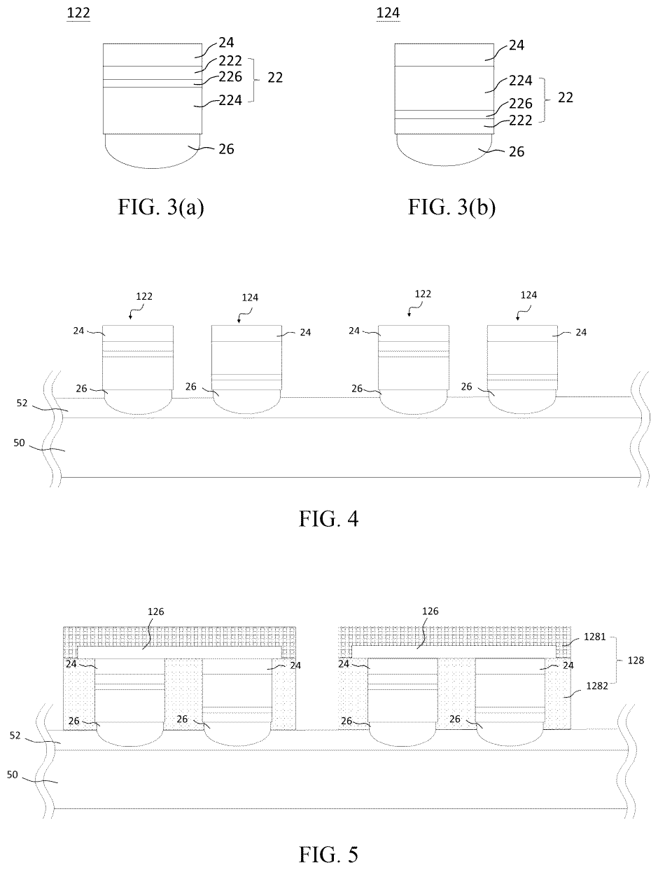

FIG. 3(a) shows a cross-sectional view of a first light-emitting unit 122 according to one embodiment, and FIG. 3(b) shows a cross-sectional view of a second light-emitting unit 124 according to one embodiment. The first light-emitting unit 122 and the second light-emitting unit 124 include a semiconductor stack 22, an upper electrode 24, and a lower electrode 26. The upper electrode 24 and the lower electrode 26 are located on opposite sides of the semiconductor stack 22 and are electrically connected to the semiconductor stack 22. The semiconductor stack 22 includes a first semiconductor layer 222, a second semiconductor layer 224, and an active layer 226, wherein the active layer 226 is located between the first semiconductor layer 222 and the second semiconductor layer 224. In the first light-emitting unit 122, the first semiconductor layer 222 is located between the upper electrode 24 and the active layer 226, and the second semiconductor layer 224 is located between the lower electrode 26 and the active layer 226. In the second light-emitting unit 124, the second semiconductor layer 224 is located between the upper electrode 24 and the active layer 226, and the first semiconductor layer 222 is located between the lower electrode 26 and the active layer 226. In one embodiment, the first semiconductor layer 222 includes a p-type semiconductor layer, and the second semiconductor layer 224 includes an n-type semiconductor layer. In other words, the first semiconductor layer 222 and the second semiconductor layer 224 have different polarities.

When a current flow into the semiconductor stack 22 through the upper electrode 24 or the lower electrode 26, the active layer 226 emits light (for example, red, blue, or green light). The upper electrode 24 is transparent (or has high transmittance) to the light emitted from the active layer 226. In one embodiment, the upper electrode 24 and the light-transmitting layer 126 are made of the same material, such as ITO or IZO. In one embodiment, an ohmic contact layer (not shown) is further provided between the upper electrode 24 and the semiconductor stack 22 to reduce the contact resistance between the upper electrode 24 and the semiconductor stack 22. In one embodiment, an ohmic contact layer (not shown) is provided between the lower electrode 26 and the semiconductor stack 22 to reduce the contact resistance between the lower electrode 26 and the semiconductor stack 22. The ohmic contact layer includes semiconductor materials, such as gallium arsenide (GaAs).

Referring again to FIG. 2. The first sub-pixel unit 12 further includes an encapsulation layer 128, which surrounds the first light-emitting unit 122 and the second light-emitting unit 124 and fills the space between the first light-emitting unit 122 and the second light-emitting unit 124. At least a portion of the lower electrode 26 of the first and second light-emitting units 122, 124 is not located within the encapsulation layer 128 for electrical connection to the contact electrode BP of the substrate 10. In one embodiment, the lower electrode 26 includes a metal layer, and the metal layer may be made of materials such as copper (Cu), titanium (Ti), aluminum (Al), tin (Sn), gold (Au), alloys thereof, or laminated layers thereof.

The encapsulation layer 128 covers the side surfaces of the light-emitting units 122 and 124, as well as the side surface of the light-transmitting layer 126, and also covers the upper surface of the light-transmitting layer 126. In another embodiment, the upper surface of the encapsulation layer 128 is coplanar with the upper surface of the light-transmitting layer 126 (not shown), so that the upper surface of the light-transmitting layer 126 is exposed from the encapsulation layer 128. In another embodiment, the encapsulation layer 128 surrounds the side surfaces of the light-emitting units 122 and 124, but the upper surface and at least a portion of the side surface of the light-transmitting layer 126 are exposed from the encapsulation layer 128 (not shown).

As shown in FIG. 2, the encapsulation layer 128 includes a first sub-encapsulation layer 1281 and a second sub-encapsulation layer 1282, wherein the first sub-encapsulation layer 1281 is located above the second sub-encapsulation layer 1282. The first sub-encapsulation layer 1281 covers the upper and side surfaces of the light-transmitting layer 126, and the light emitted by the light-emitting units 122 and 124 can pass through the first sub-encapsulation layer 1281. The second sub-encapsulation layer 1282 surrounds the light-emitting units 122 and 124, and connects to the first sub-encapsulation layer 1281. The first sub-encapsulation layer 1281 and the second sub-encapsulation layer 1282 include polymer materials that are transparent to visible light, such as epoxy, silicone, or photo-imageable dielectric (PID). The photo-imageable dielectric may include epoxy, polyimide (PI), benzocyclobutene (BCB), polybenzoxazole (PBO), or combinations thereof. In one embodiment, the first sub-encapsulation layer 1281 and the second sub-encapsulation layer 1282 can be made of the same or different materials. If the materials are the same, there may be no distinct interface between the first sub-encapsulation layer 1281 and the second sub-encapsulation layer 1282. In one embodiment, the second sub-encapsulation layer 1282 contains dark substances such as carbon black, giving it a dark appearance and allowing it to absorb at least a portion of the light from the sidewalls of the light-emitting units 122 and 124. In another embodiment, the second sub-encapsulation layer 1282 contains reflective substances such as titanium oxide (TiOₓ), giving it a white appearance and allowing it to reflect light from the sidewalls of the light-emitting units 122 and 124 upwards.

In one embodiment, the lower surface of the first sub-encapsulation layer 1281 is coplanar with the lower surface of the light-transmitting layer 126, and the upper surface of the second sub-encapsulation layer 1282 is connected to the lower surface of the light-transmitting layer 126. In another embodiment, the lower surface of the first sub-encapsulation layer 1281 is not coplanar with the lower surface of the light-transmitting layer 126 (not shown). In one embodiment, the lower surface of the second sub-encapsulation layer 1282 is higher than the lower electrode 26. In another embodiment, the second sub-encapsulation layer 1282 covers at least a portion of the lower electrode 26 but does not contact the substrate 10 (not shown).

As shown in FIG. 2, in one embodiment, the second sub-pixel unit 14 and the third sub-pixel unit 16 have the same or similar structure as the first sub-pixel unit 12, but the materials of the semiconductor stack 22 of the first and second light-emitting units 122, 124 in the second and third sub-pixel units 14, 16 are different from that in the first sub-pixel unit 12, so that the first and second light-emitting units 122 and 124 of the second and third sub-pixel units 14 and 16 can emit different color lights from that of the first sub-pixel unit 12. In one embodiment, the first sub-pixel unit 12 emits blue light, the second sub-pixel unit 14 emits green light, and the third sub-pixel unit 16 emits red light. In the first and second sub-pixel units 12, 14, the semiconductor stacks 22 of the first and second light-emitting unit 122, 124 include gallium nitride (GaN) materials. In the third sub-pixel unit 16, the semiconductor stacks 22 of the first and second light-emitting unit 122, 124 include aluminum gallium indium phosphide (AlGaInP) quaternary materials.

FIGS. 4 and 5 show a manufacturing process of a sub-pixel unit according to one embodiment. As shown in FIG. 4, a temporary carrier 50 and an adhesive layer 52 are provided, wherein the adhesive layer 52 is located on the upper surface of the temporary carrier 50. A plurality of first and second light-emitting units 122, 124 are arranged on the adhesive layer 52, and the lower electrodes 26 of the light-emitting units 122 and 124 are adhered to the adhesive layer 52. In one embodiment, at least a portion of the lower electrodes 26 of the light-emitting units 122 and 124 are embedded in the adhesive layer 52 to increase the adhesion strength.

As shown in FIG. 5, the second sub-encapsulation layer 1282 is formed on the outside of the light-emitting units 122 and 124, and the light-transmitting layer 126 is formed on adjacent light-emitting units 122 and 124 to connect them in series. If the second sub-encapsulation layer 1282 directly contacts the adhesive layer 52, the position of the lower surface of the second sub-encapsulation layer 1282 can be modified by adjusting the depth at which the lower electrode 26 is embedded in the adhesive layer 52. In one embodiment, if the upper surface of the second sub-encapsulation layer 1282 is higher than that of the upper electrode 24 before forming the light-transmitting layer 126, the second sub-encapsulation layer 1282 needs to be thinned (e.g., by a dry etching process) so that its upper surface is flush with or lower than the upper surface of the upper electrode 24. This ensures that the upper surface of the upper electrode 24 remains exposed for the subsequent formation of the light-transmitting layer 126. In one embodiment, the raw material for the second sub-encapsulation layer 1282 is deposited as a continuous film on the temporary carrier 50 by spin coating. A portion of this continuous film located between adjacent sub-pixel units is then removed, for example, by an inductively coupled plasma (ICP) process, to form two isolated second sub-encapsulation layers 1282. In another embodiment, the first sub-encapsulation layer 1281 and the second sub-encapsulation layer 1282 are fabricated using the same process. For example, the raw materials for the first sub-encapsulation layer 1281 and the second sub-encapsulation layer 1282 are each deposited as continuous films, and portions of both films between adjacent sub-pixel units are removed, for instance by ICP, to yield the respective first and second sub-encapsulation layers.

As shown in FIG. 5, the first light-emitting unit 122 and the second light-emitting unit 124 are connected to the light-transmitting layer 126 via upper electrodes 24 having different polarities. In another embodiment, the light-transmitting layer 126 further covers the side surface of the upper electrode 24 (not shown). For example, when the upper surface of the second sub-encapsulation layer 1282 is slightly lower than that of the upper electrode 24, the light-transmitting layer 126 may extend over both the side surface and the upper surface of the upper electrode 24. In another embodiment, the first and second light-emitting units 122 and 124 do not include the upper electrode 24 (not shown), and the light-transmitting layer 126 is formed directly on the semiconductor stacks 22 of the respective light-emitting units.

To form the structure illustrated in FIG. 2, the structure illustrated in FIG. 5 is first transferred onto a temporary substrate (not shown) and then transferred onto the substrate 10. The spacing between two adjacent light-emitting units 122 and 124, as illustrated in FIG. 4, is substantially equal to the spacing between two adjacent contact electrodes BP, as illustrated in FIG. 2.

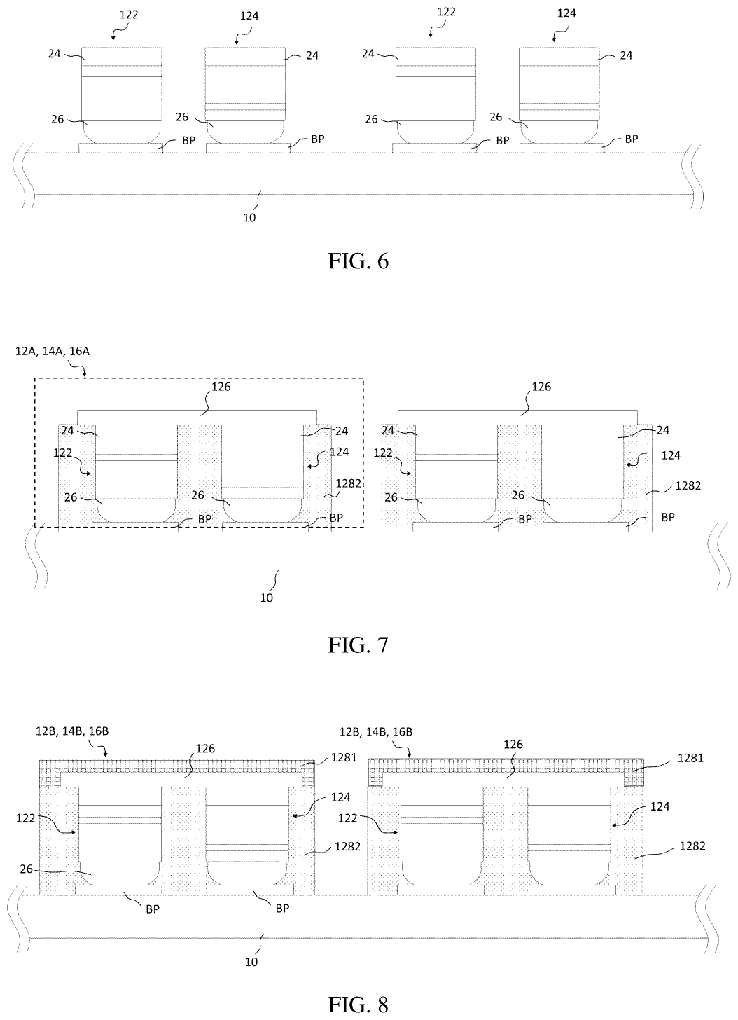

FIGS. 6 to 8 illustrate a manufacturing process of a sub-pixel unit according to another embodiment. As shown in FIG. 6, in one embodiment, the lower electrodes 26 of the first light-emitting unit 122 and the second light-emitting unit 124 are connected to the contact electrodes BP of the substrate 10. The electrical connection between the lower electrodes 26 and the contact electrodes BP may be achieved by heating and melting, optionally with additional solder (e.g., tin solder). In another embodiment, a plurality of first light-emitting units 122 are arranged on a temporary carrier (not shown) with exposing the lower electrode 26, and then transferred by means of laser transfer, for example, to be electrically connected to the contact electrode BP. The second light-emitting units 124 are subsequently transferred to the corresponding contact electrodes BP in the same manner. In another embodiment, a plurality of first light-emitting units 122 and second light-emitting units 124 are arranged together on a temporary carrier (not shown) with their lower electrodes 26 exposed, and then transferred simultaneously, such as by laser transfer, to be electrically connected to the substrate 10.

As shown in FIG. 7, the second sub-encapsulation layer 1282 is formed on the substrate 10 to surround the first light-emitting unit 122 and the second light-emitting unit 124. The light-transmitting layer 126 is then formed over the adjacent first and second light-emitting units 122, 124 to respectively define the first sub-pixel unit 12A, the second sub-pixel unit 14A, and the third sub-pixel unit 16A. The upper surface of the second sub-encapsulation layer 1282 is substantially coplanar with the upper surfaces of the light-emitting units 122, allowing the light-transmitting layer 126 to be formed on both the second sub-encapsulation layer 1282 and the light-emitting units 122, 124. In one embodiment, the second sub-encapsulation layer 1282 covers the exposed surfaces of the lower electrodes 26 and the upper surface of the substrate 10. In one embodiment, the light-transmitting layer 126 is formed on the upper electrodes 24 of the light-emitting units 122, 124. In one embodiment, the light-transmitting layer 126 covers both the upper and side surfaces of the upper electrodes 24 (not shown). In one embodiment, the light-emitting units 122, 124 do not include the upper electrode 24 (not shown), and the light-transmitting layer 126 is formed directly on the semiconductor stacks 22.

As shown in FIG. 8, the first sub-encapsulation layer 1281 is formed on the light-transmitting layer 126 to form the first sub-pixel unit 12B, the second sub-pixel unit 14B, or the third sub-pixel unit 16B. The first sub-encapsulation layer 1281 covers the upper and side surfaces of the light-transmitting layer 126 and the upper surface of the second sub-encapsulation layer 1282. The method for forming the first sub-encapsulation layer 1281 and the second sub-encapsulation layer 1282 can be referred to the above descriptions.

FIG. 9 shows a cross-sectional view of sub-pixel units 12′, 14′, and 16′ according to one embodiment. In one embodiment, the sub-pixel units 12′, 14′, and 16′ include a light guide layer 129, which is disposed above the light-transmitting layer 126 and covers the first light-emitting unit 122 and the second light-emitting unit 124. Light emitted from the light-emitting units 122 and 124 passes outward through the light guide layer 129, which adjusts the emission angle of the light. For example, the light guide layer 129 is capable of narrowing or widening the emission angle of light emitted from the light-emitting units 122 and 124. The upper surface of the light guide layer 129 includes a plurality of protrusions configured to reduce total internal reflection between the sub-pixel units 12′, 14′, and 16′ and the surrounding medium, thereby increasing the light output brightness directly above the sub-pixel units. In one embodiment, the light guide layer 129 includes semiconductor materials, glass, or plastic. The semiconductor materials include gallium nitride (GaN) or gallium phosphide (GaP), and can be etched, such as by a dry etching process, to form an upper surface having a plurality of protrusions. The structure and manufacturing process of the sub-pixel units 12′, 14′, and 16′ can be referred to the relevant figures and descriptions of the sub-pixel units 12, 14, and 16.

The first sub-encapsulation layer 1281 is disposed between the light guide layer 129 and the light-transmitting layer 126. In one embodiment, the light guide layer 129 is bonded to the light-transmitting layer 126 via the first sub-encapsulation layer 1281. As illustrated in FIG. 9, the width of the light guide layer 129 is greater than that of the light-transmitting layer 126. Light emitted from the light-emitting units 122 and 124 passes through the light-transmitting layer 126 toward the light guide layer 129. In another embodiment, the width of the light guide layer 129 is equal to that of the light-transmitting layer 126. In this configuration, the light-transmitting layer 126 separates the first sub-encapsulation layer 1281 from the second sub-encapsulation layer 1282 (not shown), and the side surfaces of the light guide layer 129, the first sub-encapsulation layer 1281, the light-transmitting layer 126, and the second sub-encapsulation layer 1282 are flush with each other.

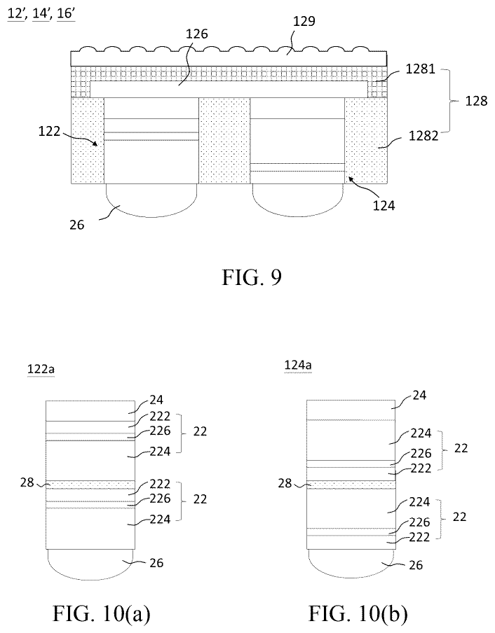

Please refer to FIG. 10. In one embodiment, the first light-emitting unit 122a and/or the second light-emitting unit 124a includes multiple semiconductor stacks 22, and the multiple semiconductor stacks 22 are connected by a connecting layer 28. In one embodiment, the connecting layer 28 electrically connects the semiconductor stacks 22, so that when a current is applied to the light-emitting units 122a, 124a, the active layers of the semiconductor stacks 22 emit light. In one embodiment, the connecting layer 28 includes a semiconductor material or an oxide material, wherein the semiconductor material contains elements present in the semiconductor stack 22, and the oxide material contains materials of the aforementioned light-transmitting layer 126. In one embodiment, the connecting layer 28 comprises a tunnel junction. The description of the first light-emitting unit 122a and/or the second light-emitting unit 124a can refer to FIG. 3 and the related paragraphs. In one embodiment, the light-emitting units 122a, 124a include N semiconductor stacks 22 and N-1 connecting layers 28, wherein two adjacent semiconductor stacks 22 are connected via a connecting layer 28, and N is a positive integer. In one embodiment, due to process tolerances, the semiconductor stacks 22 located on the two sides of the connecting layer 28 have different thicknesses. For example, in the first light-emitting unit 122a, the semiconductor stack 22 located above the connecting layer 28 has a smaller thickness than the semiconductor stack 22 located below the connecting layer 28.

In one embodiment, the second light-emitting unit 124 of the sub-pixel units 12, 14, and 16 in FIG. 2 is replaced by the second light-emitting unit 124a of FIG. 10(b), with the first light-emitting unit 122 and the second light-emitting unit 124a connected in series via the light-transmitting layer 126. In another embodiment, the first light-emitting unit 122 of the sub-pixel units 12, 14, and 16 in FIG. 2 is replaced by the first light-emitting unit 122a of FIG. 10(a), with the first light-emitting unit 122a and the second light-emitting unit 124 connected in series via the light-transmitting layer 126. In yet another embodiment, the first light-emitting unit 122 of the sub-pixel units 12, 14, and 16 in FIG. 2 is replaced by the first light-emitting unit 122a of FIG. 10(a), and the second light-emitting unit 124 is replaced by the second light-emitting unit 124b of FIG. 10(b), with the first light-emitting unit 122a and the second light-emitting unit 124b connected in series via the light-transmitting layer 126. In a further embodiment, in the sub-pixel units 12A, 14A, 16A of FIG. 7, the sub-pixel units 12B, 14B, 16B of FIG. 8, or the sub-pixel units 12′, 14′, 16′ of FIG. 9, the first light-emitting unit 122 and/or the second light-emitting unit 124 is replaced by the light-emitting units 122a and/or 124a of FIG. 10.

As shown in FIG. 1, in one embodiment, the first sub-pixel unit 12 includes gallium nitride (GaN) materials and is configured to emit blue light, the second sub-pixel unit 14 includes gallium nitride (GaN) materials and is configured to emit green light, and the third sub-pixel unit 16 includes aluminum gallium indium phosphide (AlGaInP) materials and is configured to emit red light. The first sub-pixel unit 12 and the second sub-pixel unit 14 respectively include the light-emitting units 122 and 124 illustrated in FIG. 3. The third sub-pixel unit 16 includes (i) the first light-emitting unit 122 of FIG. 3 and the second light-emitting unit 124a of FIG. 10, or (ii) the first light-emitting unit 122a of FIG. 10 and the second light-emitting unit 124 of FIG. 3. The first sub-pixel unit 12 and the third sub-pixel unit 16 have similar forward voltages. For example, the forward voltage difference between the first sub-pixel unit 12 and the third sub-pixel unit 16 is less than 3 V, 2 V, 1 V, or 0.5 V. In one embodiment, the first sub-pixel unit 12 has a forward voltage of approximately 6 V, with the light-emitting units 122 and 124 each having a forward voltage of about 3 V. The third sub-pixel unit 16 has a forward voltage of approximately 6.4 V, with the first light-emitting unit 122 having a forward voltage of about 1.9 V, and the second light-emitting unit 124a having a forward voltage of about 4.5 V.

The present disclosure provides a display module in which each sub-pixel unit includes two vertical light-emitting diodes connected in series via a light-transmitting layer, thereby reducing the power consumption of the display circuit. In addition, the spacing between the two light-emitting units in each sub-pixel unit can be adjusted according to the positions of the contact electrodes on the circuit substrate, thereby reducing the manufacturing complexity associated with connecting the sub-pixel unit to the circuit substrate.

Although the present disclosure has been described with reference to the foregoing embodiments, these embodiments are not intended to limit the scope of the present disclosure. Various modifications, equivalents, and alternatives will be apparent to those of ordinary skill in the art without departing from the spirit and scope of the present disclosure. Accordingly, the scope of protection of the present disclosure shall be defined by the appended claims.

1. A display module, comprising:
a substrate;
a first sub-pixel unit, disposed on the substrate, and comprising a first light-emitting unit, a second light-emitting unit, and a light-transmitting layer, wherein the first light-emitting unit and the second light-emitting unit are connected in series through the light-transmitting layer, and are located on a same side of the light-transmitting layer; and
a second sub-pixel unit, disposed on the substrate, wherein the first sub-pixel unit and the second sub-pixel unit are configured to emit different color lights.

2. The display module of claim 1, wherein the first light-emitting unit and the second light-emitting unit are disposed between the substrate and the light-transmitting layer, and do not overlap with each other.

3. The display module of claim 1, wherein the first sub-pixel unit further comprises an encapsulation layer encapsulating the first light-emitting unit, the second light-emitting unit, and the light-transmitting layer.

4. The display module of claim 3, wherein the first light-emitting unit comprises a lower electrode exposed from the encapsulation layer.

5. The display module of claim 1, wherein the light-transmitting layer is not in contact with the second sub-pixel unit.

6. The display module of claim 1, wherein the light-transmitting layer is not in contact with the second sub-pixel unit.

7. A method of manufacturing a display module, comprising:
providing a substrate, a first sub-pixel unit and a second sub-pixel unit, wherein the first sub-pixel unit and the second sub-pixel unit are configured to emit different color lights, the first sub-pixel unit comprises a first light-emitting unit with a first electrode, and a second light-emitting unit with a second electrode;
bonding the first sub-pixel unit to the substrate, wherein the first electrode and the second electrode are bonded to the substrate; and
bonding the second sub-pixel unit to the substrate.

8. The method of claim 7, wherein the first sub-pixel unit further comprises a light-transmitting layer which is arranged to connect the first light-emitting unit and the second light-emitting unit in series.

9. The method of claim 8, wherein the first sub-pixel unit further comprises a light guide layer arranged to cover the light-transmitting layer.

10. The method of claim 7, wherein the first sub-pixel unit further comprises an encapsulation layer arranged over the first light-emitting unit and the second light-emitting unit.
